(19) United States
(12) Patent Application Publication
(10) Pub. No.: US 2005/0206424 A1
(43) Pub. Date: Sep. 22, 2005

(54) Current selective D flip-flop circuit

(75) Inventors: Ye Dajun, Singapore (SG); Chee Piew Yoong, Singapore (SG); Yong Siong Siew, Singapore (SG)

Correspondence Address: CONLEY ROSE, P.C., P. O. BOX 3267, HOUSTON, TX, 77253-3267, US

(73) Assignee: AGENCY FOR SCIENCE, TECHNOLOGY AND RESEARCH, Singapore (SG)

(21) Appl. No.: 10/801,455

(22) Filed: Mar. 16, 2004

(51) Int. Cl. H03B 19/00

(52) U.S. Cl. 327/218

(57) ABSTRACT

An embodiment of a current selective D flip-flop circuit comprises a D flip-flop, a current selector and a current multiplier is disclosed. The current selector is used for receiving and summing at least two currents to form a summed current and having a current comparator for comparing the summed current with one of the at least two currents and selecting one of the at least two currents as an output current. The output current is steered through the current multiplier for biasing the D flip-flop.

### FIELD OF INVENTION

The invention relates generally to D flip-flop circuits. In particular, the invention relates to a D flip-flop circuit having current selective biasing properties.

### BACKGROUND

Prescaler circuits that operate at the gigahertz (GHz) frequency range are essential for frequency synthesizing in wireless telecommunication systems. The prescaler circuit predominantly determines the power consumption of a frequency synthesizer. This has prompted various methods to be proposed for reducing the power consumption of the prescaler circuit.

Current-mode D flip-flops (D-FF) are extensively used in prescaler circuit designs and typically determine the speed and power consumption of the prescaler circuit. In particular, two key parameters dictate the speed and power consumption of the prescaler circuit, namely output voltage swing and biasing current.

In a prescaler circuit, the subsequent stage of a current-mode D-FF is triggered by the output voltage swing of the current-mode D-FF of the previous stage. Hence, maintaining the magnitude of the current-mode D-FF output voltage swing is critical for the operation of the prescaler circuit.

A current-mode D-FF is shown in FIG. 1 for receiving data and clock signals and providing output signals. The current-mode D-FF 100 is typically configured as a master-slave pair. The master-slave pair comprises cross-coupled D-latches, 101 and 102 respectively. Each of the cross-coupled D-latches, 101 and 102 has two output nodes while each output node is connected to a voltage supply VDD through a load resistor RL. There is also an associated parasitic capacitance CL at each of the output node. The output voltage swing Vₒ of the current-mode D-FF 100 is represented by:
Vₒ=R_{L}*I_{Bias}.
where R_{L} is the load resistance of the load resistor and I_{Bias} is the biasing current.

A biasing circuit 103 is used to provide a biasing current I_{Bias} 103 for the transistors of the D-latches 101 and 102, which are designed to operate at high speed. The operating speed for the D-latches 101 and 102 is limited by the time for the parasitic capacitances to charge and discharge through the load resistor. Therefore parasitic capacitance, load resistance and biasing current are important parameters in determining the operating speed of the D-latches 101 and 102.

In order to achieve maximum operating speed with a predetermined biasing current, parasitic capacitance and load resistance are to be kept at a minimum. The output voltage swing can be determined once the minimized parasitic capacitance and load resistance are realised. An appropriate biasing current is then selected to achieve the maximum operating speed and minimum power consumption.

In practice, resistance of the load resistors varies over process corners, which also vary the output voltage swing. Process corners typically arise from ambient temperature change or fabrication process drift of the load resistor. This makes fulfilling the requirements of maximum operating speed and minimum power consumption over all process corners very challenging.

There are two conventional methods for designing the biasing current for the current-mode D-FF 100. The first conventional method is typically for generating a desired biasing current using an on-chip resistor biased with a bandgap reference voltage. The desired biasing current I_{Bias} is represented by:

$${I}_{Bias} = \frac{{V}_{ref}}{R}$$

where V_{ref} is the bandgap reference voltage that is independent over process corners and R is the resistance of a biasing current circuit.

An on-chip resistor is similar to the output impedances of the current-mode D-FF 100 and is dependent on process corners.

The second conventional method used to design the biasing current of the current-mode D-FF 100 is to use a constant biasing source, such as a constant transconductance biasing network, or replacing the on-chip resistor with an external resistor. In this second method, the desired biasing current is then made process corner independent. This second method of maintaining a constant biasing current across the whole range of the process corners is however not power efficient. There are instances during the operation of the current-mode D-FF 100 whereby maintaining a constant biasing current exceeds operating requirements.

Accordingly there is a need for a method for ensuring optimal current usage and for achieving low power consumption and maintaining high operating speed across the whole range of the process corners.

### SUMMARY

Embodiments of the invention disclosed herein possess improved performance relating to current usage for achieving low power consumption and maintaining high operating speed.

Therefore, in relation with the above described embodiments of the invention, there is disclosed a current selective D flip-flop circuit for receiving at least two currents and performing current selection. The current selective D flip-flop circuit for receiving at least two currents and performing current selection comprises a D flip-flop and, a first receiving means for receiving a first current and having a first receiving means output terminal for providing the first current and, a second receiving means for receiving a second current and having a second receiving means output terminal for providing the second current. The first receiving means output terminal is connected to the second receiving means output terminal at a summing node for summing the first current and the second current to obtain a summed current. A current comparator is connected to the summing node for comparing the summed current with the second current to thereby select one of the first current and the second biasing current as an output current for biasing the D flip-flop, wherein the one of at least two current is receivable from an on-chip biasing current source and the other of the one of at least two current is receivable from a constant biasing source, according to a first aspect of the invention.

In accordance with a second aspect of the invention, there is disclosed a method for performing biasing current selection, the method comprising the steps of applying a first current to an input terminal of a first receiving means and a second current to an input terminal of a second receiving means. Providing the first current from an output terminal of the first receiving mean and the second current from an output terminal of the second receiving means. Summing the first current and the second current to produce a summed current at a summing node. Comparing the summed current with the second current by a current comparator and selecting one of the first current and the second current as an output current by the current comparator in response to the summed current and the second current being compared.

In accordance with a third aspect of the invention, there is disclosed a current selective D flip-flop circuit capable of performing biasing current selection, the current selective D flip-flop circuit comprises a D flip-flop, a current selector circuit couplable to the D flip-flop and a current multiplier, wherein the current selector circuit is coupled to the D flip-flop through the current multiplier.

### BRIEF DESCRIPTION OF THE DRAWING

Embodiments of the invention are described hereinafter with reference to the drawings, in which:

FIG. 1 is a prior art schematic diagram of a current-mode D flip-flop;

FIG. 2 is a schematic diagram of a current selector circuit according to an embodiment of the invention;

FIG. 3 is a schematic diagram of a current selective D flip-flop circuit incorporating the current-mode D flip-flop of FIG. 1 and the current selector circuit of FIG. 2 according to a further embodiment of the invention;

FIG. 4a is a chart illustrating a conventional biasing current characteristics of the current-mode D flip-flop of FIG. 1 when using an on-chip biasing source or a constant biasing source; and

FIG. 4b is a chart illustrating biasing current characteristics of the current selective D flip flop of FIG. 3 when using the on-chip biasing source or the constant biasing source.

### DETAILED DESCRIPTION

With reference to the drawings, a current selector circuit according to an embodiment of the invention for receiving at least two currents and performing current selection is disclosed for addressing the needs of low power consumption and maintaining high operating speed across a whole range of process corners. Various biasing methods for enabling high speed operation have been previously proposed. However, these methods do not allow low power consumption to be achieved under process corners variations.

For purposes of brevity and clarity, the description of the invention is limited hereinafter to MOS transistors. This however does not preclude the application of embodiments of the invention to other circuit variations such as when BJT transistors or MOS transistors of various properties are used for achieving similar operating performance. The functional principles of circuitry fundamental to the embodiments of the invention remain the same throughout the variations.

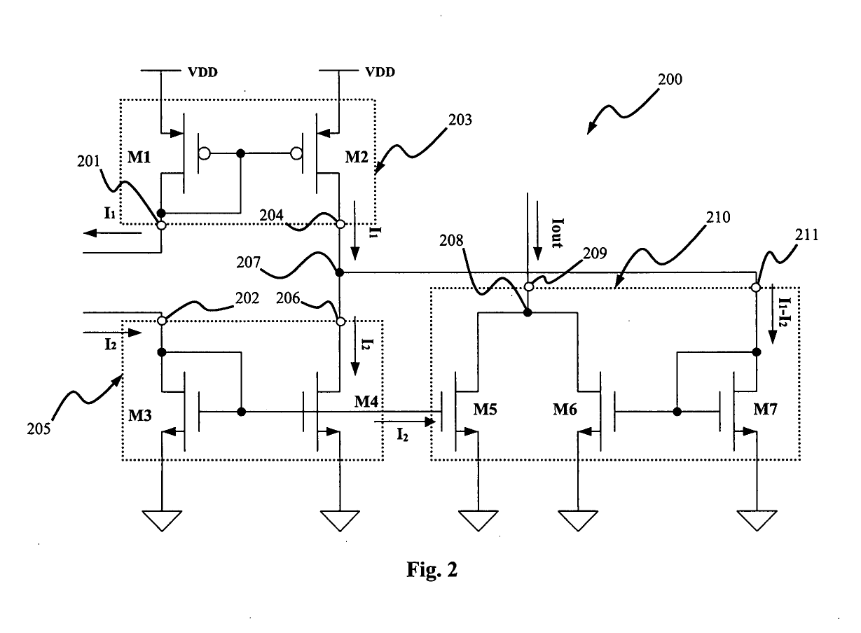

In a preferred embodiment of the invention described with reference to FIG. 2, a current selector circuit 200 on a chip for receiving at least two biasing currents and performing current selection is disclosed. A first current I₁ is preferably generated by an on-chip biasing current source, such as a current source having an on-chip resistor biased with a bandgap reference voltage. The first current I₁ is received by the current selector circuit 200 via a first receiving means input terminal 201. A second current I₂ is preferably generated by a constant biasing source, such as a current source having an external resistor biased with the bandgap reference voltage. The second current I₂ is received by the current selector circuit 200 via a second receiving means input terminal 202.

The first receiving means 203 comprises a first current mirror. The first receiving means 203 preferably comprises a transistor M1 and a transistor M2 having interconnected gates that are further connected to the drain of transistor M1. The drain of the transistor M1 is connected to the first receiving means input terminal 201 for receiving the first biasing current I₁. The sources of transistor M1 and M2 are connected to a voltage supply VDD. The drain of transistor M2 is connected to a first receiving means output terminal 204.

The second receiving means 205 comprises a second current mirror. The second receiving means 205 preferably comprises a transistor M3 and a transistor M4 having interconnected gates that are further connected to the drain of transistor M3. The drain of transistor M3 is connected to the second receiving means input terminal 202 for receiving the second current I₂. The sources of transistor M3 and M4 are connected to a reference voltage, for example ground. The drain of transistor M4 is connected to a second receiving means output terminal 206 and is further connected to the first receiving means output terminal 204 to form a summed node 207.

A current comparator 210 comprises a third current mirror and a transistor M5.

Transistor M5 is connected in parallel to the second receiving means 205 whereby the gate of transistor M5 is connected to the gates of transistor M3 and M4. The source of transistor M5 is connected to a reference voltage, preferably ground.

The third current mirror preferably comprises a transistor M6 and a transistor M7 having interconnected gates that are further connected to the drain of transistor M7. The drain of transistor M7 is connected to a current comparator input terminal 211 and is further connected to the summed node 207. The drain of transistor M6 is connected to the drain of transistor M5 to form an output node 208 which is connected to an output terminal 209 for providing an output current Iₒᵤₜ to bias a current mode D-FF.

Alternatively, each of the first receiving means 203, the second receiving means 205 and the third current mirror comprises more than two transistors.

The first current mirror of the first receiving means 203 preferably comprises PMOS transistors while the second current mirror of the second receiving means 205 and the current comparator 210 preferably comprises NMOS transistors.

The process in which the current selector circuit 200 accepts and compares two currents and selects one of the two biasing currents as an output current Iₒᵤₜ is better understood by the following circuit analysis.

First and second currents I₁ and I₂ are respectively applied to the first and second receiving means input terminal, 201 and 202. First and second currents I₁ and I₂ are then respectively mirrored at the first and second receiving means output terminals, 204 and 206, due to and dependent on the current mirror configurations and properties of the first receiving means 203 and the second receiving means 205 respectively. Currents I₁ and I₂ are summed at the summed node 207 to produce a summed current I₁-I₂ at the current comparator input terminal 211. The second current I₂ appears at the drain of transistor M5 due to current steering effects from the second receiving means 205.

According to Kirchhoff's first law, when the first current I₁ is greater than the second current I₂, the summed current I₁-I₂ is the difference between the first current I₁ and the second current I₂. This summed current I₁- I₂ is then applied to the current comparator input terminal 211 and appears at the drain of transistor M6 due to current mirror configurations of the third current mirror. This summed current I_{I}- I₂ is then summed with the second current I₂ at the output node 208 to provide the output current Iₒᵤₜ through the output terminal 209. Applying Kirchhoff's first law to the output node 209, the output current Iₒᵤₜ is equal to the first current I₁.

When the first current I₁ is equivalent to the second current I₂, the two currents cancel each other out to thereby produce no summed current I₁-I₂. This results in transistors M6 and M7 of the third current mirror being switched off. The output current lout is then equivalent to the first current I₁ or the second current I₂.

Transistors M6 and M7 of the third current mirror are also switched off when the first current I₁ is less than the second current I₂ to thereby equate the output current Iₒᵤₜ with the second current I₂.

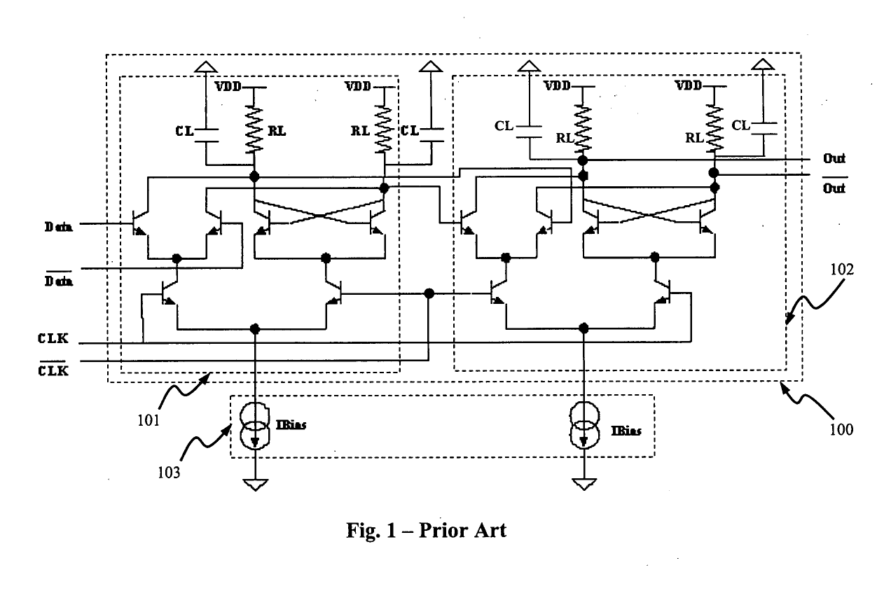

Hence, the current selector circuit 200 accepts and compares the first current I₁ and the second current I₂ before selecting a current with larger magnitude as the output current Iₒᵤₜ for biasing the current-mode D-FF 100 of FIG. 1.

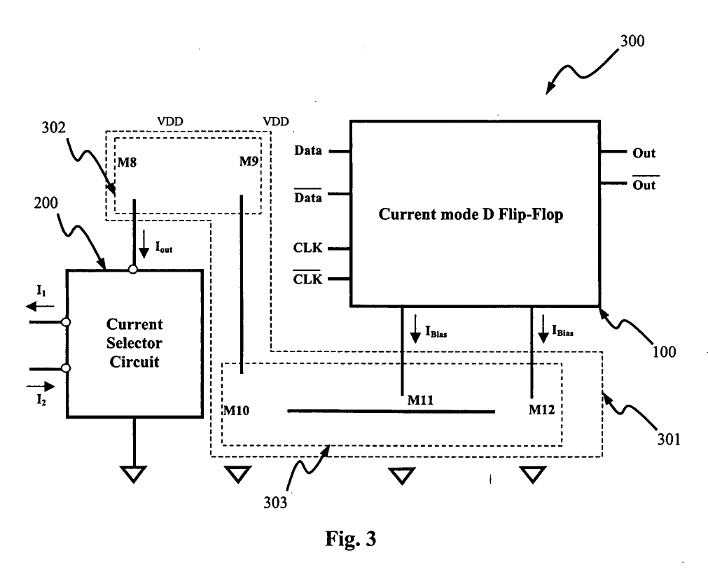

A current selective D Flip-Flop 300 is shown in FIG. 3. The current selective D Flip-Flop 300 comprises the current selector circuit 200 and the current-mode D-FF 100. The output terminal 209 of the current selector circuit 200 is preferably coupled to the current-mode D-FF 100 through a current multiplier 301.

The current multiplier 301 preferably comprises a current mirror source 302 and a multiple-output current mirror 303. The current mirror source 302 preferably comprises two transistors M8 and M9 having interconnected gates that are further connected to the drain of transistor M8. The sources of both transistors M8 and M9 are connected to the voltage supply VDD. The drain of the transistor M8 is connected to the output terminal 209 of the current selector circuit 200. The drain of the transistor M9 is connected to the drain a transistor M10 of the multiple-output current mirror 303. The multiple-output current mirror 303 preferably comprises three transistors M10, M11 and M12 having interconnected gates. The drains of the two transistors M11 and M12 of the multiple-output current mirror 303 are connected to the current-mode D-FF 100 for providing biasing currents I_{Bias} thereto. The sources of the three transistors M10, M11 and M12 of the multiple-output current mirror 303 are connected to a reference voltage, for example ground. The current multiplier 301 therefore multiplies and steers the output current Iₒᵤₜ to biasing currents I_{Bias} for biasing the current-mode D-FF 100. The current multiplier 301 can also bias multiple current-mode D-FFs when modified appropriately with the addition of further transistors configured like transistors M11 and M12.

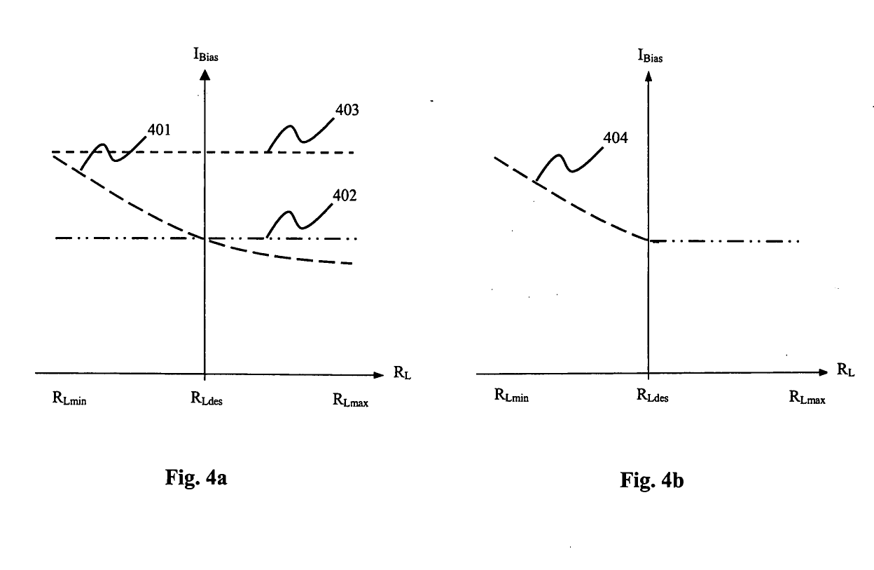

In a conventional situation, the biasing current characteristics of the current-mode D-FF 100 when biased with an on-chip biasing source or a constant biasing source are shown in FIG. 4a. The resistance of the on-chip resistor is assumed to vary by a typical ±15% about a designed value R_{Ldes}.

Curve 401 represents the biasing current characteristics of the current-mode D-FF 100 when a biasing source with on-chip resistor is used. Curve 401 defines the output voltage swing requirement of the current-mode D-FF 100.

Curve 402 represents the biasing current characteristics of the current-mode D-FF100 when a constant biasing source such as an external resistor biased with a bandgap reference voltage is used. Curve 402 curve defines the operating speed requirement of the current-mode D-FF 100.

Curve 403 represents the biasing current characteristics of the current-mode D-FF 100 when the constant biasing source is used to provide a higher biasing current. The higher biasing current is needed in order to meet both the output voltage swing and the operating speed requirements of the current-mode D-FF 100.

Curve 404 of FIG. 4b shows the biasing current characteristics of the current selective D Flip Flop 300. The current selective D Flip Flop 300 is selectively biased with an on-chip biasing source or a constant biasing source. By allowing the first and second current I₁ and I₂ to be generated respectively from the on-chip biasing circuit and constant biasing source, the embodiment of the invention is capable of selecting an appropriate biasing current for the current-mode D-FF 100. This means that the current selective D Flip-Flop 300 maintains an optimum current usage while achieving the required speed performance.

With the incorporation of the current selector circuit 200 in the current selective D Flip-Flop 300, a maximum saving of 15% in current usage can be achieved over the constant biasing source represented by curve 403, assuming process variation of the on-chip resistor is ±15%. At the same time, power consumption is significant reduced as compared to the constant biasing source.

The current selective D-FF 300 is also implementable in various analog blocks that require high-speed divider circuits that are sensitive to process variations. The current selective D-FF 300 is particularly suitable for high-speed divider application in frequency synthesizers that require low power consumption.

In the foregoing manner, a current selector circuit for D flip-flop is described according to an embodiment of the invention for addressing the foregoing problems ensuring optimal current usage for achieving low power consumption and maintaining high operating speed for conventional circuits. Although only one embodiment of the invention is disclosed, it will be apparent to one skilled in the art in view of this disclosure that numerous changes and/or modification can be made without departing from the scope and spirit of the invention.

1. A current selective D flip-flop circuit on a chip for receiving at least two currents and performing biasing current selection, comprising:
a D flip-flop;
a first receiving means having a first receiving means input terminal for receiving one of at least two currents and having a first receiving means output terminal for providing a first current, the first current being dependent on the one of at least two currents;
a second receiving means having a second receiving means input terminal for receiving another of the at least two currents and having a second receiving means output terminal for providing the second current, the second current being dependent on the another of the at least two currents;
a summing node to which a first receiving means output terminal is connected to the second receiving means output terminal for summing the first current and the second current to obtain a summed current therefrom; and
a current comparator having a current comparator input terminal connected to the summing node, wherein the current comparator is coupled to the second receiving means for comparing the summed current with the second current to thereby select one of the first current and the second current as an output current for biasing the D flip-flop, and the one of the at least two current is receivable from an on-chip biasing current source and the other of the one of the at least two current is receivable from a constant biasing source.

2. The current selector circuit of claim 1, wherein the current selector circuit is coupled to the D flip-flop through a current multiplier, wherein the current multiplier comprises:
a current mirror source being coupled to the current selector circuit; and
a multiple-output current mirror being coupled to the current mirror source and the D flip-flop.

3. The current selector circuit of claim 1, wherein the first receiving means comprises a first current mirror.

4. The biasing current selector circuit of claim 3, the first current mirror comprising at least two PMOS transistors.

5. The current selector circuit of claim 1, wherein the second receiving means comprises a second current mirror.

6. The current selector circuit of claim 5, the second current mirror comprising at least two NMOS transistors, and the second receiving means output terminal being connected to the first receiving means output terminal.

7. The current selector circuit of claim 1, the current comparator comprising:
a third current mirror connected to the drain of a transistor to form an output node, wherein the output node is connected to an output terminal for providing the output current to the D flip-flop through the current multiplier.

8. The biasing current selector circuit of claim 7, the third current mirror comprising:
a current comparator input terminal connected to the summing node; and
at least two NMOS transistors.

9. The current selector circuit of claim 1, wherein a voltage supply is connected to the first current mirror.

10. The current selector circuit of claim 1, wherein the second receiving means and the current comparator is connected to ground.

11. The current selector circuit of claim 1, the output current being selected by the current comparator from one of the first current and second current having a larger current magnitude.

12. A method for performing biasing current selection in a current selective D flip-flop circuit, the method comprising the steps of:
applying a first and a second current to a first receiving means input terminal of a first receiving means and a second current to a second receiving means input terminal of a second receiving means;
providing the first current from a first receiving means output terminal of the first receiving means;
providing the second current from a second receiving means output terminal of the second receiving means;
summing the first current and the second current to produce a summed current at a summing node;
comparing the summed current with the second current by a current comparator; and
selecting one of the first current and the second current as an output current by the current comparator in response to the summed current and the second current being compared.

13. The method of claim 12, the step of providing a first current from a first receiving means output terminal comprising the step of providing the first current from the first receiving means having at least two PMOS transistors.

14. The method of claim 12, the step of providing a second current from a second receiving means output terminal comprising the step of providing the second current from the second receiving means output terminal with the second receiving means output terminal being connected to the first receiving means output terminal.

15. The method of claim 12, the step of comparing the summed current with the second current by a current comparator comprising the step of:
providing the current comparator having a third current mirror connected to the drain of a transistor to form an output node, wherein the output node is connected to an output terminal for providing the output current thereat to the D flip-flop.

16. The method of claim 15, the step of providing the current comparator having a third current mirror comprising the steps of:
providing the current comparator having a third current mirror comprising:
a current comparator input terminal connected to the summing node for receiving the summed current thereat; and
at least two NMOS transistors.

17. The method of claim 12, the step of providing the first current from a first receiving means output terminal comprising the step of:
providing the first receiving means with a voltage supply connected thereto.

18. The method of claim 12, the step of providing the second current from a second receiving means output terminal comprising the step of:
providing the second receiving means and the current comparator with a connection to ground.

19. The method of claim 12, the step of comparing the summed current with the second current by a current comparator comprising the step of:
comparing the current magnitude of each of the summed current and the second current.

20. The method of claim 19, the step of selecting one of the first current and the second current as an output current comprising the step of:
selecting one of the first current and second current having a larger current magnitude.

21. A current selective D flip-flop circuit capable of performing biasing current selection, the current selective D flip-flop circuit comprising:
a D flip-flop;
a current selector circuit couplable to the D flip-flop; and
a current multiplier;
wherein the current selector circuit is coupled to the D flip-flop through the current multiplier.

22. The current selective D flip-flop circuit of claim 21, wherein the current multiplier comprises:
a current mirror source being coupled to the current selector circuit; and
a multiple-output current mirror being coupled to the current mirror source and the D flip-flop.
